(19) United States
(12) Patent Application Publication
(10) Pub. No.: US 2024/0110274 A1
(43) Pub. Date: Apr. 4, 2024

(54) VAPOR DEPOSITION METHOD AND VAPOR DEPOSITION CONTAINER

(71) Applicant: FUJFILM Corporation, Tokyo (JP)

(72) Inventors: Yoshihiko MOCHIZUKI, Minamiashigara-shi (JP); Mitsuru IWATA, Minamiashigara-shi (JP); Yasunori YONEKUTA, Minamiashigara-shi (JP)

(73) Assignee: FUJFILM Corporation, Tokyo (JP)

(21) Appl. No.: 18/470,500

(22) Filed: Sep. 20, 2023

(30) Foreign Application Priority Data
Sep. 29, 2022 (JP) 2022-156503

(51) Int. Cl. C23C 14/24

(52) U.S. Cl. CPC C23C 14/243

(57) ABSTRACT

Provided is a vapor deposition method in which a deposition rate can be kept constant, it is not needed to unnecessarily increase a container temperature for improving a deposition rate, and vapor deposition of even a powder material that is easily thermally decomposed can be performed at a desired deposition rate, in vacuum vapor deposition using a powder material.

The method is provided by using a container including an accommodating portion configured to accommodate the powder material and at least one opening for releasing vapor of the powder material from the accommodating portion, to perform the vacuum vapor deposition of the powder material by heating the container, in which, in a case where an area of an inner surface of the accommodating portion is S and a total area of the opening is O, a ratio of the total area O of the opening to the area S of the inner surface is 0.06% to 2% as a percentage of O/S.

### CROSS-REFERENCE TO RELATED APPLICATIONS

The present application claims priority under 35 U.S.C. § 119 to Japanese Patent Application No. 2022-156503, filed on Sep. 29, 2022. The above application is hereby expressly incorporated by reference, in its entirety, into the present application.

### BACKGROUND OF THE INVENTION

### 1. Field of the Invention

The present invention relates to a vapor deposition method for performing vacuum vapor deposition of a powder material and a vapor deposition container used in the vapor deposition method.

### 2. Description of the Related Art

In general, in vacuum vapor deposition, a container containing a material is heated, and a desired amount of the material is vaporized and deposited on a substrate by appropriately adjusting a temperature of the container.

Here, in the vacuum vapor deposition, in order to form an appropriate film, it is needed to appropriately control a deposition amount of the material onto a substrate side per unit time, that is, a deposition rate, and to perform vapor deposition at a stable and constant deposition rate.

For example, in manufacture of an organic electro luminescence (EL) display, an organic EL thin film is formed on a transparent substrate.

Here, in film formation of the organic EL thin film, a plurality of materials having different boiling points (sublimation points) may be simultaneously vapor-deposited. In this case, in a case where the deposition rate varies even with one material, a component of the organic EL thin film that is formed varies, and it is not possible to form an appropriate organic EL thin film.

Accordingly, various proposals have been made for keeping the deposition rate constant in the vacuum vapor deposition.

For example, in WO2006/075401A, an evaporation source that includes a container in which an evaporation material or a sublimation material is accommodated, an opening portion that is disposed at an upper portion of the container and controls an amount of a material evaporated or sublimated in the container to be released out of the container, an bumping substance cutting plate that is disposed under the opening portion and cuts an bumping substance obtained as the evaporation material or the sublimation material in the container bumps from being released out of the container, and a heater that heats the bumping substance cutting plate, and a vapor deposition apparatus that uses the evaporation source are disclosed.

### SUMMARY OF THE INVENTION

By using the evaporation source according to WO2006/075401A, it is possible to suppress release of a material from the evaporation source even in a case where the material bumps.

Release of a material to an outside of an evaporation source due to bumping is a cause of a variation in a deposition rate. Therefore, by using the evaporation source according to WO2006/075401A, it is possible to suitably suppress a variation in a deposition rate due to bumping of a material.

However, there are various factors other than bumping as factors for a variation in a deposition rate in the vacuum vapor deposition, and emergence of a vacuum vapor deposition method capable of keeping a deposition rate constant is desired.

An object of the present invention is to solve the above-described problem of the related art and to provide, in the vacuum vapor deposition in which a powder material is vapor-deposited, a vapor deposition method that is capable of keeping a deposition rate constant, moreover, is capable of suppressing an increase in a container temperature for improving a deposition rate, and enables performing vacuum vapor deposition of even a powder material that is easily thermally decomposed at a desired deposition rate.

In order to solve the above-described problem, the present invention has the following configurations.

[1] A vapor deposition method comprising, in performing vacuum vapor deposition of a powder material, as a container for accommodating and heating the powder material, using a container including an accommodating portion configured to accommodate the powder material and at least one opening for releasing vapor of the powder material from the accommodating portion, to perform the vacuum vapor deposition of the powder material by heating the container, in which, in a case where an area of an inner surface of the accommodating portion is S and a total area of the opening is O, a ratio of the total area O of the opening to the area S of the inner surface is 0.06% to 2% as a percentage of O/S.

[2] The vapor deposition method according to [1], in which the container includes a plurality of the openings.

[3] The vapor deposition method according to [1] or [2], in which an area of the opening is 1 mm² or less.

[4] The vapor deposition method according to any one of [1] to [3], in which the openings are spaced apart from each other by 1 mm or more.

[5] The vapor deposition method according to any one of [1] to [4], in which the opening is circular.

[6] The vapor deposition method according to any one of [1] to [5], in which, in a case where a bottom area of the accommodating portion is Sb, a ratio of the bottom area Sb to the area S of the inner surface is 20% or more as a percentage of Sb/S in the container.

[7] The vapor deposition method according to any one of [1] to [6], in which a difference between a vaporization temperature and a decomposition temperature of the powder material is 70° C. or lower.

[8] The vapor deposition method according to any one of [1] to [7], in which the powder material is sublimable.

[9] The vapor deposition method according to any one of [1] to [8], in which the container includes a container main body that forms at least a part of the accommodating portion, and a lid body that includes the opening and engages with the container main body, and the container main body and the lid body are formed of a material that generates heat by energization.

The vapor deposition method according to any one of [1] to [9], in which the vapor deposition of the powder material is performed while a volume of the powder material is kept in a range of 50% to 5% of a capacity of the accommodating portion.

A vapor deposition container that accommodates and heats a material of which vapor deposition is performed in a case of performing vacuum vapor deposition, the vapor deposition container comprising an accommodating portion configured to accommodate the material, and at least one opening for releasing vapor of the material from the accommodating portion, in which, in a case where an area of an inner surface of the accommodating portion is S and a total area of the opening is O, a ratio of the total area O of the opening to the area S of the inner surface is 0.06% to 2% as a percentage of O/S.

According to the present invention, in the vacuum vapor deposition in which a powder material is vapor-deposited, it is possible to keep a deposition rate constant, moreover, to suppress the increase in the container temperature for improving a deposition rate, and to perform the vacuum vapor deposition of even a powder material that is easily thermally decomposed at a desired deposition rate.

### BRIEF DESCRIPTION OF THE DRAWINGS

FIG. 1 is a diagram conceptually showing an example of a vapor deposition method according to an embodiment of the present invention.

FIG. 2 is a diagram conceptually showing an example of a vapor deposition container according to the embodiment of the present invention used in the vapor deposition method according to the embodiment of the present invention.

FIG. 3 is a diagram conceptually showing another example of the vapor deposition container according to the embodiment of the present invention used in the vapor deposition method according to the embodiment of the present invention.

FIG. 4 is a conceptual diagram for explaining the vapor deposition method according to the embodiment of the present invention.

FIG. 5 is a diagram conceptually showing another example of a container used in the vapor deposition method according to the embodiment of the present invention.

FIG. 6 is a diagram conceptually showing another example of a container used in the vapor deposition method according to the embodiment of the present invention.

FIG. 7 is a diagram conceptually showing another example of a container used in the vapor deposition method according to the embodiment of the present invention.

FIG. 8 is a diagram conceptually showing another example of a container used in the vapor deposition method according to the embodiment of the present invention.

FIG. 9 is a diagram conceptually showing another example of a container used in the vapor deposition method according to the embodiment of the present invention.

### DESCRIPTION OF THE PREFERRED EMBODIMENTS

Hereinafter, a vapor deposition method and a vapor deposition container will be described in detail based on suitable Examples shown in the accompanying drawings.

It should be noted that each of the drawings shown below is a conceptual diagram for describing the present invention, and a shape, a size, a positional relationship, and the like of each member, each opening, and the like are different from those of an actual object.

In addition, in the present invention, a numerical range expressed using “to” means a range including numerical values indicated before and after “to” as a lower limit value and an upper limit value.

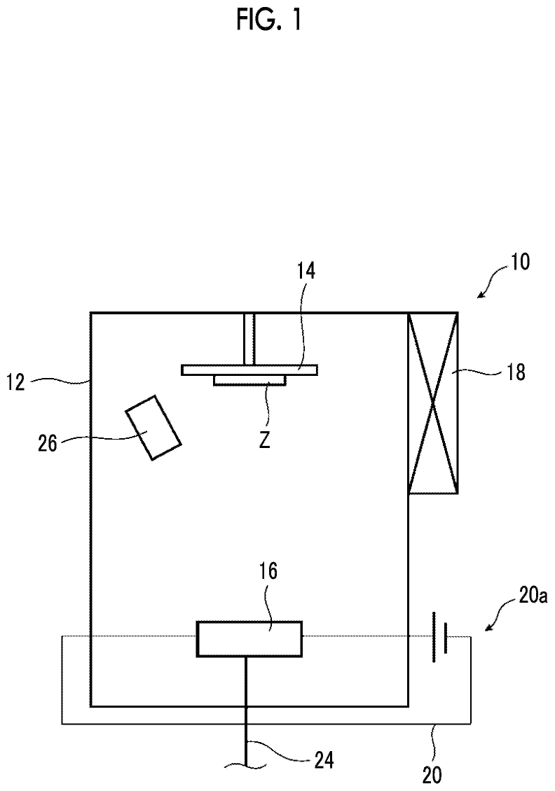

An example of a vapor deposition apparatus that implements the vapor deposition method according to an embodiment of the present invention is conceptually shown in FIG. 1.

A vapor deposition apparatus 10 shown in FIG. 1 is an apparatus that performs vapor deposition of a powder material on a substrate Z by the vapor deposition method according to the embodiment of the present invention. As shown in FIG. 1, the vapor deposition apparatus 10 has a vacuum chamber 12, a substrate holder 14, a container 16, a vacuum exhaust unit 18, a heating unit 20, a temperature measuring unit 24, and a rate monitor 26.

In the vapor deposition apparatus 10 of the illustrated example, the container 16 accommodates a powder material of which vapor deposition is performed and heats the powder material to vaporize (evaporate) the powder material. In the vapor deposition apparatus that implements the vapor deposition method according to the embodiment of the present invention, the container 16 is the vapor deposition container according to the embodiment of the present invention.

The vapor deposition apparatus 10 of the illustrated example, that is, the vapor deposition method according to the embodiment of the present invention is basically similar to a known vacuum vapor deposition apparatus and a vacuum vapor deposition method, except that vacuum vapor deposition of a powder material is performed using a predetermined container, that is, the vapor deposition container according to the embodiment of the present invention.

Therefore, as the vacuum chamber 12, the substrate holder 14, the vacuum exhaust unit 18, the heating unit 20, the temperature measuring unit 24, and the rate monitor 26, various known products that are used in a normal vapor deposition apparatus can be used.

Each member is fixed or mounted in the vacuum chamber 12 by a known method. Further, the substrate Z is attachably and detachably mounted in the substrate holder 14 by a known method.

In addition, the substrate holder 14 may perform operation for suppressing film thickness distribution performed by a known vapor deposition apparatus, such as rotation and/or reciprocation of the substrate Z, as needed. In addition, a plurality of vacuum exhaust units 18 may be provided as needed.

Further, in the vapor deposition apparatus performing the vapor deposition method according to the embodiment of the present invention, in addition to the members illustrated, various members provided in a known vapor deposition apparatus such as a heating unit for the substrate Z, a shutter for cutting vapor discharged from the container 16, an air supply pipe and an opening/closing unit of the air supply pipe for returning an inside of the vacuum chamber 12 to atmospheric pressure, an introducing unit for an inert gas, a pressure-measuring unit for measuring pressure inside the vacuum chamber 12, and the like may be provided.

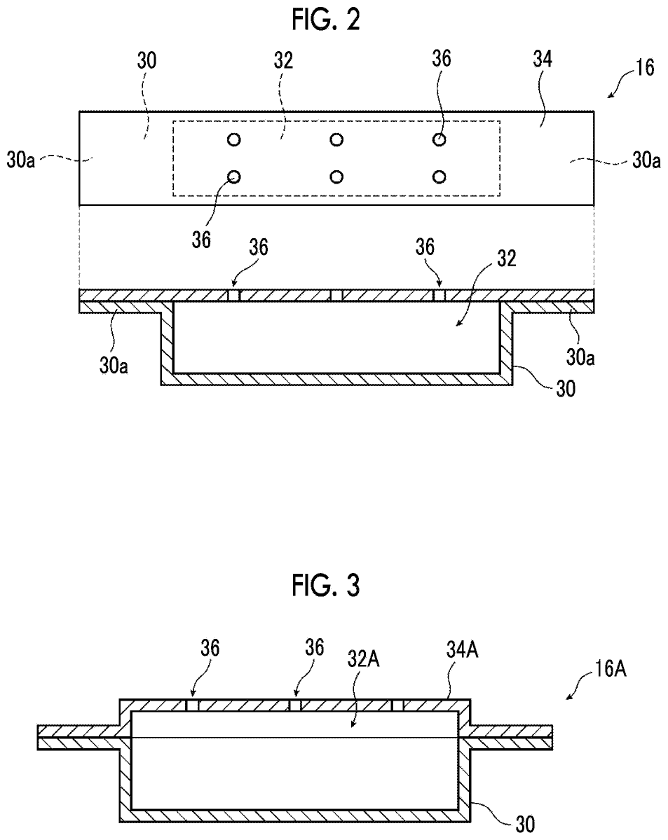

The container 16 is conceptually shown in FIG. 2.

The container 16 in the illustrated example has a container main body 30 and a lid body 34.

The container main body 30 mainly forms an accommodating portion 32 that accommodates a powder material, and has the accommodating portion 32 having a rectangular cuboid shape that is formed such that a recess is provided in a center of a rectangular plate-like object, a flange portion 30a that protrudes from an upper end of the accommodating portion 32 in a longitudinal direction of a rectangle. Therefore, a planar shape of the container main body 30 is a rectangle.

The lid body 34 is a rectangular plate-like member having the same planar shape as the container main body 30, and is engaged with the container main body 30 such that outer perimeters in a plane direction coincide with each other. In addition, an opening 36 for releasing vapor of a powder material from the accommodating portion 32 is formed in a region of the lid body 34 corresponding to the accommodating portion 32.

Therefore, the accommodating portion 32 is composed of the recess of the container main body 30 and the region of the lid body 34 that blocks the recess of the container main body 30.

The container 16 is formed, as shown in FIG. 2, by stacking the container main body 30 and the lid body 34 such that the outer perimeters thereof coincide with each other, and by fixing the flange portion 30a of the container main body 30 and a portion of the lid body 34 corresponding to the flange portion 30a, for example, with a clamp.

The container 16 will be described in detail later.

In the vapor deposition apparatus 10 shown in FIG. 1, the container main body 30 and the lid body 34 are formed of a material that generates heat by energization, and the heating unit 20 energizes the container 16 by a DC power source 20a to cause the container 16 to generate heat so that a powder material is heated.

However, in the vapor deposition method according to the embodiment of the present invention, the heating method for a powder material, that is, the container 16 is not limited thereto, various heating methods for a container (evaporation source (vapor deposition source)) used in the vacuum vapor deposition such as a method for heating the container 16 with an external heater, a method using radiant heat, and the like can be used.

Here, in the present invention, it is preferable to heat a powder material not only by a portion in contact with the container, but also by radiant heat generated by heating a region that the powder material of the container is not in contact with, by heating the entire container that accommodates the powder material. In consideration of this point, as a heating unit for a powder material, as in the illustrated example, the method of heating a powder material by using a container that generates heat by energization and by causing the container to generate heat by energization is suitably used.

The point will be described in detail later.

In an example shown in FIG. 1, only the one container 16 (evaporation source) and the one heating unit 20 for the container 16 are provided, but the present invention is not limited thereto. That is, in the vapor deposition method according to the embodiment of the present invention, a plurality of containers 16 and heating units 20 respectively provided for the containers 16 may be provided, and vapor deposition of a plurality of powder materials may be simultaneously performed on the substrate Z.

In addition, in the present invention, in a case of simultaneously performing vapor deposition of a plurality of materials, vapor deposited of the other materials may be performed by a known method as long as vapor deposition of at least one powder material is performed by the vapor deposition method according to the embodiment of the present invention.

In the vapor deposition method according to the embodiment of the present invention, there is no limitation on vapor deposition conditions (film formation conditions) in the vacuum vapor deposition such as a degree of vacuum (pressure) in the vacuum chamber 12, a container temperature at which a powder material is heated, an input power gradient and a time until the container 16 reaches a predetermined temperature, a distance between the substrate Z and the container 16, a substrate temperature, a rotational speed of substrate rotation, and the like.

That is, in the vapor deposition method according to the embodiment of the present invention, the vapor deposition conditions need only be appropriately set in accordance with a powder material that is vapor-deposited, a material forming the substrate Z, a target deposition rate, target film structure and target film composition, and the like.

In the vapor deposition method according to the embodiment of the present invention, there is no limitation on the substrate Z on which a powder material is vapor-deposited, various products can be used as long as the products have sufficient heat resistance in accordance with the vapor deposition conditions.

As the substrate Z, as an example, a substrate consisting of silicon, glass, sapphire, gallium nitride, polyimide, polyethylene terephthalate (PET), polyethylene naphthalate (PEN), and the like is exemplified.

In the vapor deposition method according to the embodiment of the present invention, the substrate Z is not limited to a plate-like object (sheet-like object, film), and various articles can be used as the substrate Z.

In addition, in the vapor deposition method according to the embodiment of the present invention, a powder material that is vapor-deposited on the substrate Z is not limited, and powders consisting of various known materials can be used as long as vacuum vapor deposition is possible.

As will be described later, in the vapor deposition method according to the embodiment of the present invention, it is possible to perform vapor deposition at a constant and favorable deposition rate by suppressing an increase in the container temperature for improving a deposition rate. That is, the vapor deposition method according to the embodiment of the present invention can be suitably used for vapor deposition of a powder material consisting of an organic compound having low heat resistance.

In addition, in consideration of this point, the vapor deposition method according to the embodiment of the present invention can be suitably used for vapor deposition of a powder material that is easily thermally decomposed. That is, in the vapor deposition method according to the embodiment of the present invention, even with a powder material in which a difference between a vaporization temperature and a decomposition temperature is small, it is possible to suitably prevent thermal decomposition to perform vapor deposition.

Specifically, the vapor deposition method according to the embodiment of the present invention is suitably used for vapor deposition of a powder material in which a difference between a vaporization temperature and a decomposition temperature is 70° C. or lower, more preferably 60° C. or lower, and still more preferably 50° C. or lower.

Further, as will be described later, in the vapor deposition method according to the embodiment of the present invention, even with a sublimable material of which a deposition rate is difficult to stabilize, it is possible to keep a deposition rate constant. As is well known, a sublimable material is a material that evaporates (sublimates) from a solid matter without passing through a liquid to become a gas.

In consideration of this point, the present invention is suitably used for vapor deposition of a sublimable material.

Therefore, the vapor deposition method according to the embodiment of the present invention is suitably used for vapor deposition of a sublimable organic compound.

In the present invention, specifically, examples of a powder material that is vapor-deposited on the substrate Z include general organic compounds used as materials for electronic products. More specifically, examples thereof include an organic compound used as a positive hole transportation material, an organic compound used as an electron transportation material, an organic compound used as an organic electroluminescence element material, an organic compound used as an organic photoelectric conversion material, an organic compound used as an organic solar cell, an organic compound used as an organic thin film transistor, an organic compound used as an organic biosensor, an organic compound used as an organic memory, an organic compound used as an organic thermoelectric conversion material, and the like.

In the present invention, a powder material refers to a material generally referred to as a powder, a granular material, or the like.

Specifically, in the present invention, a powder material is a powder, a particulate, a granular material, or the like in a particle size range of 0.1 nm to 1 mm.

As described above, the vapor deposition apparatus shown in FIG. 1 implements the vapor deposition method according to the embodiment of the present invention.

Therefore, the vapor deposition apparatus 10 uses the predetermined container 16 (the vapor deposition container according to the embodiment of the present invention) as a container for accommodating, heating, and vaporizing a powder material that is vapor-deposited, and performs vacuum vapor deposition of the powder material on the substrate Z.

In the vapor deposition method according to the embodiment of the present invention, the container has an accommodating portion that accommodates a powder material and one or more openings for releasing the vapor of the powder material from the accommodating portion. In addition, in the container, in a case where an area of an inner surface of the accommodating portion is S and a sum of areas of the openings, that is, a total area of the openings is O, a ratio of the total area O of the openings to the area S of the inner surface is 0.06% to 2% as a percentage of O/S.

In the following description, for convenience, the area S of the inner surface of the accommodating portion is also referred to as “inner surface area S”, and the total area O of the openings is also referred to as “total opening area O”.

As described above, in the vapor deposition apparatus 10 of the illustrated example, the container 16 mainly has a configuration in which the container main body 30 having the recess forming the accommodating portion 32 and the plate-like lid body 34 having the same rectangular planar shape as the container main body 30 are stacked such that the outer perimeters coincide with each other.

In addition, in the illustrated example, the lid body 34 has six openings 36 for releasing the vapor of the powder material from the accommodating portion 32 in the region corresponding to the accommodating portion 32.

Therefore, a sum of an area of an inner wall surface (side surface and bottom surface) of the recess of the container main body 30 forming a space serving as the accommodating portion 32 and an area of the lid body 34 also forming the space serving as the accommodating portion 32, that is, an area of a region shown by a broken line in FIG. 2 is the inner surface area S of the accommodating portion 32 of the container 16.

In addition, the lid body 34 has six openings 36 for releasing vapor of a powder particle from the accommodating portion 32. Therefore, a sum of areas of the six openings is the total opening area O of the container 16.

The ratio of the total opening area O to the inner surface area S of the accommodating portion 32 of the container 16 is 0.06% to 2% as the percentage of O/S.

The present invention, by having such a configuration, in the vacuum vapor deposition using a powder material, is capable of keeping a deposition rate constant, moreover, suppresses the increase in the container temperature for improving a deposition rate, and enables performing vacuum vapor deposition of even a powder material that is easily thermally decomposed at a desired deposition rate.

In the vacuum vapor deposition, a container (evaporation source) containing a material vapor-deposited is heated and the material is vaporized, whereby the vaporized material is deposited on a substrate to perform vapor deposition (film formation). Here, in the vacuum vapor deposition, the container temperature is appropriately controlled to adjust a vaporization amount of the material by adjusting input power to the container, so that a deposition rate is kept constant.

Here, in a normal open type container, since it is difficult to uniformly heat the accommodated material, bumping or the like occurs, and it is difficult keep the deposition rate constant.

In particular, in a sublimable material that vaporizes from a powder (solid matter) state without passing through a liquid state, a contact state between the container serving as a heating source and a powder material is non-uniform and changes every moment. Moreover, since it is not liquefied, it is not uniformly leveled in the container as in a case of a liquid.

Therefore, in vacuum vapor deposition using a sublimable powder material, it is difficult to uniformly heat the powder material, and it is difficult to keep a deposition rate constant.

With respect to this, there is also known a container for vapor deposition in which an open surface of the container for accommodating and heating a material is covered with a lid body having a plurality of openings to prevent abnormal scattering of the material.

However, in the container, sufficient controllability cannot be obtained, for example, although vapor that vaporizes and directly proceeds to the openings is released from the container, vapor that comes into contact with a portion other than the openings of the lid body is cooled and returns to a solid matter repeatedly. Therefore, in a container having the lid body, it is not possible to obtain a sufficient effect of stabilizing a deposition rate in a powder material having poor heat transfer efficiency, such as an organic compound.

The present inventors have made extensive studies on such a problem.

As a result, in the vacuum vapor deposition of a powder material, it has been found that the vapor deposition can be performed while a deposition rate is suitably kept constant by placing a container for accommodating and heating a powder material in a semi-sealed state, setting a saturated vapor pressure such that a gas and a solid matter are in an equilibrium state (gas-solid matter equilibrium state), and heating the container at a constant temperature to perform the vapor deposition.

As conceptually shown in FIG. 4, in the vacuum vapor deposition, by reducing a size of a vapor releasing opening of a container for accommodating and heating a material to place the container in the semi-sealed state, it becomes difficult for vapor shown by a broken line, which has vaporized, to be directly released from the container.

As a result, a state in which vapor and a powder material (solid line) are mixed in the container in the semi-sealed state is obtained, and an inside of the container is in the saturated vapor pressure that is in the gas-solid matter equilibrium state in which no more vapor that has vaporized is generated in accordance with the container temperature.

In this state, only vapor that has reached the opening of the container is released in a constant amount in accordance with the saturated vapor pressure. In addition, in accordance with the container temperature, the powder material is vaporized only in the amount of the powder material released from the opening to keep the gas-solid matter equilibrium state.

By setting the saturated vapor pressure and by performing the vapor deposition in this manner, the release of vapor from the opening in the constant amount and the vaporization of the powder material in the constant amount in accordance with the release of the vapor are continuously performed as a result.

That is, by placing a container in the semi-sealed state to retain vapor in the container, setting a saturated vapor pressure that is in the gas-solid matter equilibrium state, and heating the container at a constant temperature to perform vapor deposition, it is possible to keep an evaporation amount of a material per unit time constant to keep an amount of vapor released from the container constant, and as a result, it is possible to perform the vapor deposition while a deposition rate is suitably kept constant.

In order to heat a container in the semi-sealed state at a constant temperature to set a saturated vapor pressure that is in the gas-solid matter equilibrium state, it is advantageous to reduce a size of a vapor releasing opening in the container so that the container is close to a sealed state.

However, on the other hand, in a case where a size of a vapor releasing opening is reduced, an amount of released vapor is small and a deposition rate is low.

As a method of increasing a deposition rate, there is a method of increasing a container temperature to increase a saturated vapor pressure. However, in the method, although a deposition rate is improved, depending on a powder material, thermal decomposition may occur in a container, and a target film may not be vapor-deposited. That is, in a case where the container is brought close to the sealed state and a powder material is an organic compound having low heat resistance such as an organic EL material and an organic photoelectric conversion material, it is not possible to vapor-deposit a desired film at a sufficient deposition rate.

With respect to this, in the vapor deposition method according to the embodiment of the present invention and the vapor deposition container according to the embodiment of the present invention, as a container for accommodating, heating, and vaporizing a powder material in the vacuum vapor deposition, a container in which the ratio of the total opening area O to the inner surface area S of the accommodating portion 32 of the container 16 is 0.06% to 2% as the percentage of O/S is used.

In the following description, for convenience, the percentage of the ratio O/S of the total opening area O to the inner surface area S of the accommodating portion 32 of the container 16 is also be referred to as “opening ratio O/S”.

According to the vapor deposition method according to the embodiment of the present invention, by setting the opening ratio O/S to 2% or less, an inside of the accommodating portion 32 can be suitably set to a saturated vapor pressure in the gas-solid matter equilibrium state by heating the container 16. As a result, even in a case of a sublimable powder material, it is possible to suitably keep a deposition rate constant by heating of the container 16 at a constant temperature. In addition, by setting the opening ratio O/S to 0.06% or more, an opening area sufficient to obtain a needed deposition rate can be ensured, and there is no need to set the container temperature of the container 16 to a high temperature in order to increase a deposition rate.

Therefore, according to the vapor deposition method according to the embodiment of the present invention, a deposition rate can be kept constant, moreover, the increase in the container temperature for improving a deposition rate can be suppressed, and it is possible to perform the vacuum vapor deposition of even a powder material such as an organic compound that is easily thermally decomposed at a desired deposition rate.

Further, according to the vapor deposition method according to the embodiment of the present invention, since a temperature of a powder material in the container is made constant as compared with the vapor deposition using an open-type container by setting the inside of the accommodating portion 32 to a saturated vapor pressure, purity of a vapor-deposited film is also improved.

The inner surface area S of the accommodating portion 32 is an area of an inner surface of the accommodating portion 32 including an area of the opening 36. In the illustrated example, the area of the inner surface of the accommodating portion 32 is the area of the inner surface of the accommodating portion 32 in a case where it is assumed that the lid body 34 does not have the opening 36.

That is, in the vapor deposition method according to the embodiment of the present invention, the inner surface area S of the accommodating portion of the container is the area of the inner surface of the accommodating portion in a case where it is considered that the container does not have the opening for releasing vapor of a powder particle from the accommodating portion.

In addition, in the vapor deposition method according to the embodiment of the present invention, the lid body of the container is not limited to a flat plate-like shape, and for example, as in the container 16A conceptually shown in FIG. 3, a lid body 34A, which has a protrusion protruding toward a side opposite to the container main body 30 and has the opening 36 on the protrusion, can also be used.

In this case, a space formed by the protrusion of the lid body 34A also serves as an accommodating portion 32A for accommodating a powder material. Therefore, in this case, a sum of the area of the inner wall surface of the recess of the container main body 30 forming a space serving as the accommodating portion 32A and an area of an inner wall surface of the protrusion of the lid body forming the space serving as the accommodating portion 32A is an inner surface area S of the accommodating portion of the container 16A.

In the vapor deposition method according to the embodiment of the present invention, in a case where the opening ratio O/S exceeds 2%, the inside of the accommodating portion 32 cannot be suitably set to a saturated vapor pressure, it is not possible to keep a deposition rate constant, and vapor resulting from bumping in the container 16 is easily released from the opening 36 right away, resulting in an inconvenience such as a large variation in a deposition rate.

In addition, in a case where the opening ratio O/S is less than 0.06%, a sufficient deposition rate cannot be obtained, the increase in the container temperature at which a material is heated is needed in order to obtain a needed deposition rate, resulting in an inconvenience such as occurrence of decomposition of a powder material.

In the vapor deposition method according to the embodiment of the present invention, the opening ratio O/S is preferably 0.08% to 1.7%, and more preferably 0.1% to 1.4%.

In the container 16 of the illustrated example, the lid body 34 forming the accommodating portion 32 has the six openings 36.

However, the present invention is not limited thereto, and the number of the openings 36 may be one, may be plural up to five, or may be seven or more.

Here, in the present invention, it is preferable that the number of the openings 36 for releasing vapor of a powder material from the accommodating portion 32 is plural.

In a case where the opening 36 is too large, during bumping of a powder material accommodated in the accommodating portion 32, the powder material is easily released from the opening 36 and a variation in a deposition rate due thereto easily occurs. With respect to this, by having a plurality of the openings 36, it is not needed to unnecessarily enlarge the openings 36, and the opening ratio O/S can be set to 0.06 to 2%.

The number of the openings 36 is preferably plural, more preferably 2 to 15, and still more preferably 4 to 12.

In the vapor deposition method according to the embodiment of the present invention, it is preferable that the number of the openings 36 is plural and the areas of the openings 36 are 1 mm² or less. In the present invention, although it is preferable that the areas of the one or more openings 36 are 1 mm² or less, the larger the number of the openings 36 having the area of 1 mm² or less is, the more preferable it is, and it is most preferable that the areas of all the openings 36 are 1 mm² or less.

As described above, in a case where the opening 36 is too large, during bumping of a powder material, the powder material is released from the opening 36, and the variation in a deposition rate due thereto easily occurs. With respect to this, the above is preferable from the view point of, for example, being capable of preventing the release of a powder material from the opening 36 during bumping of the powder material and of suppressing the variation in a deposition rate due thereto by setting the area of the opening 36 to 1 mm² or less.

The area of the opening 36 is more preferably 0.9 mm² or less, and still more preferably 0.8 mm² or less.

The area of the opening 36 is preferably 0.2 mm² or more, and more preferably 0.4 mm² or more.

In a case where the opening 36 is too small, there is a possibility that vapor precipitates in a case of coming into contact with the lid body 34 of the opening 36, and a material adheres to the opening 36 to block the opening 36. With respect to this, by setting the area of the opening 36 to 0.2 mm² or more, it is possible to suitably prevent the opening 36 from being blocked by a material.

In addition, in the vapor deposition method according to the embodiment of the present invention, it is preferable that the number of the openings 36 is plural and the adjacent openings 36 are spaced apart from each other by 1 mm or more. In the present invention, although it is preferable that distances between one or more sets of openings 36 are 1 mm or more, the larger the number of sets of openings 36 that are spaced apart by 1 mm or more is, the more preferable it is, and it is most preferable that distances between all the openings 36 are 1 mm or more.

In a case where the openings 36 are too close to each other, the plurality of openings 36 are combined to serve like one opening, and as in the case where the opening 36 is too large, during bumping of a powder material, the powder material is released from the opening 36, and the variation in a deposition rate due thereto easily occurs. With respect to this, the above is preferable from the viewpoint of, for example, being capable of preventing the release of a powder material from the opening 36 during bumping of the powder material and of suppressing the variation in a deposition rate due thereto by setting the distance between the adjacent openings 36 to 1 mm or more.

The distance between the adjacent openings 36 is more preferably 1.2 mm or more, and still more preferably 1.5 mm or more.

The distance between the adjacent openings 36 is preferably 10 mm or less, and more preferably 6 mm or less.

In a case where the openings 36 are too far apart from each other, there is a possibility that an inconvenience such as occurrence of a film thickness distribution of a vapor-deposited film occurs. With respect to this, by setting the distance between the adjacent openings 36 to 10 mm or less, it is possible to suitably prevent such an inconvenience from occurring.

In the present invention, the distance between the adjacent openings 36 indicates a shortest distance between end portions of the adjacent openings 36.

In the vapor deposition method according to the embodiment of the present invention, a shape of the opening 36 is not limited to a circular shape shown in the illustrated example, and various shapes such as a polygonal shape including a triangle shape, a quadrangular shape, and a pentagonal shape, an elliptical shape, and an amorphous shape can be used.

However, for example, in a case where the shape of the opening is a polygonal shape or the like such as a quadrangular shape, anisotropy occurs in a releasing direction of vapor from the opening, and the film thickness distribution of the vapor-deposited film is generated, and there is a possibility that an increase in adhesion of a material to a side surface of the accommodating portion 32 or the like easily occurs.

In consideration of this point, the shape of the opening is preferably a circular shape as shown in the illustrated example.

As will be described later, in the vapor deposition method according to the embodiment of the present invention, the shape of the container (accommodating portion) for accommodating and heating a powder material is not limited to a rectangular cuboid as in the illustrated example, and various shapes can be used.

Here, in a case where the shape of the accommodating portion is a shape having a bottom surface as in the rectangular cuboid of the illustrated example, in a case where a bottom area of the accommodating portion 32 is Sb, in the container 16, it is preferable that a ratio of the bottom area Sb to the above-described inner surface area S is 20% or more as a percentage of Sb/S.

In the following description, for convenience, the percentage of the ratio of Sb/S of the bottom area Sb to the inner surface area S is also referred to as “bottom area ratio Sb/S”.

In the accommodating portion 32 of the container 16, a bottom surface has the largest contact area with an accommodated powder material. Therefore, by relatively increasing the bottom area in the accommodating portion 32, the contact area between the powder material and the container 16 can be increased, and as a result, a vaporization amount of the powder material can be increased.

Therefore, by setting the bottom area ratio Sb/S to 20% or more, the above-mentioned advantage is more suitably exhibited, and even in a case where the heating of the container 16 is performed at a low temperature, it is possible to suitably keep the inside of the accommodating portion 32 at a saturated vapor pressure.

The bottom area ratio Sb/S is more preferably 22% or more, and still more preferably 25% or more.

In a case where the bottom area ratio Sb/S is too large, a distance between the bottom surface of the accommodating portion 32 and the opening 36 for releasing vapor of a powder material is too short, and an inconvenience such as easy release of the powder material from the accommodating portion 32 during bumping easily occurs.

In consideration of this point, the bottom area ratio Sb/S is preferably 40% or less, and more preferably 35% or less.

In the vapor deposition method according to the embodiment of the present invention, an accommodation amount of a powder material in the accommodating portion 32 is not limited and may be appropriately set in accordance with a film thickness of a film that is vapor-deposited on the substrate Z or the like.

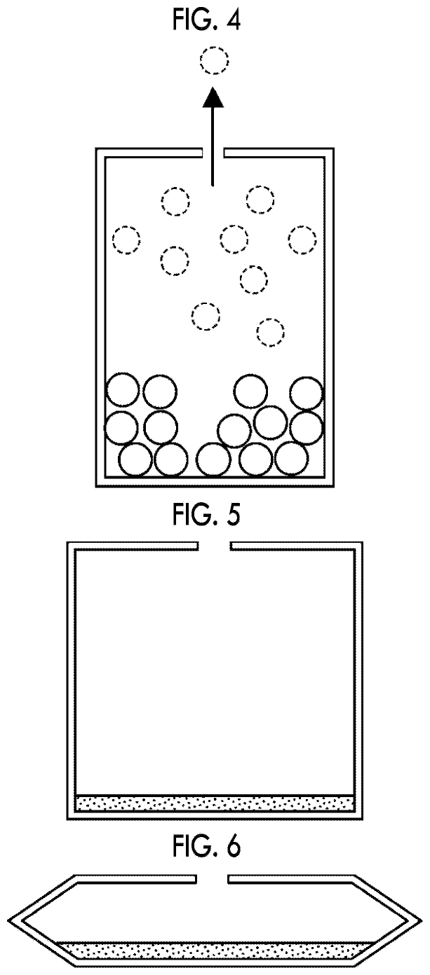

Here, as described above, in the vapor deposition method according to the embodiment of the present invention, the vapor deposition is performed while the inside of the accommodating portion 32 is kept at a saturated vapor pressure in the gas-solid matter equilibrium state. In such a vapor deposition method according to the embodiment of the present invention, it is preferable that a space to a certain extent is present in the accommodating portion 32 (refer to FIG. 5 described later).

That is, by providing a space to a certain extent in the accommodating portion 32, gas vapor of a powder material can be stored in the space. As a result, by the gas vapor stored in the space, it is possible to more suitably keep the inside of the accommodating portion 32 at a saturated vapor pressure, and it is possible to more suitably stabilize a deposition rate.

On the other hand, as the vapor deposition proceeds, an amount of a powder material in the accommodating portion 32 gradually decreases, and the space in the accommodating portion 32 mentioned above becomes wider.

As the vapor deposition progresses, the amount of the powder material in the accommodating portion 32 decreases, and, for example, a portion that is exposed without being covered with the powder material is formed on the bottom surface of the accommodating portion 32, an amount of vapor of the vaporized powder material is reduced. As a result, there is a possibility that balance with the vapor released from the opening 36 cannot be achieved, and it is not possible to keep the inside of the accommodating portion 32 at a saturated vapor pressure.

In consideration of the above point, in the vapor deposition method according to the embodiment of the present invention, it is preferable that the vapor deposition is performed such that a volume of a powder material is kept at 50% to 5% ([vol %]) of a capacity of the accommodating portion 32, that is, a spatial volume of the accommodating portion 32.

As a result, it is possible to ensure a sufficient space for the vapor of a powder material to exist in the accommodating portion 32, to suitably keep the inside of the accommodating portion 32 at a saturated vapor pressure even in a case where the vapor deposition proceeds, and to perform the vapor deposition of a powder material at a more stable deposition rate.

A volume of a powder material in the accommodating portion 32 is more preferably kept at 48% to 7% and still more preferably kept at 45% to 10% of the capacity of the accommodating portion 32.

As described above, in the vapor deposition apparatus 10 of the illustrated example, as a preferable form, the container 16 is formed as the container main body 30 and the lid body 34, which are formed of a material that generates heat by energization, are stacked and fixed with a clamp or the like. More preferably, the container main body 30 and the lid body 34 are formed of the same material that generates heat by energization.

In addition, in the vapor deposition apparatus 10, the container 16, that is, the container main body 30 and the lid body 34 are energized by the DC power source 20a to cause the container 16 to generate heat so that a powder material is heated.

In the vapor deposition method according to the embodiment of the present invention, by having such a configuration, by energizing the container 16, the entire container generates heat at the same temperature, and the accommodating portion 32 can be heated at a uniform temperature. Therefore, according to the configuration, in the inside of the accommodating portion 32, a powder material can be heated not only by the portion in which the container and the powder material are in contact, but also by the radiant heat generated by heating the region that the powder material of the container is not in contact with. As a result, it is possible to suitably keep the inside of the accommodating portion 32 at a saturated vapor pressure and to perform the vapor deposition of a powder material at a more stable deposition rate.

In the vapor deposition method according to the embodiment of the present invention, a material for forming the container 16 is not limited, and various known materials for forming a container (evaporation source, boat) used in vacuum vapor deposition can be used.

Here, for the reason described above, it is preferable that a material for forming the container 16 is a material that generates heat by energization. Specifically, examples of a material for forming the container 16 include tantalum, molybdenum, and tungsten.

In the above example, the shape of the accommodating portion 32 is a rectangular cuboid shape, but the present invention is not limited thereto, and various shapes may be used.

As an example, an accommodating portion (container) having a cubic shape conceptually shown in FIG. 5 or a rectangular cuboid shape with a high height is exemplified. According to the shape, the space in the accommodating portion described above can be easily ensured.

In addition, as conceptually shown in FIG. 6, an accommodating portion (container) having a shape in which a side surface (side wall) widens in a height direction and narrows from a center to a top can also be used.

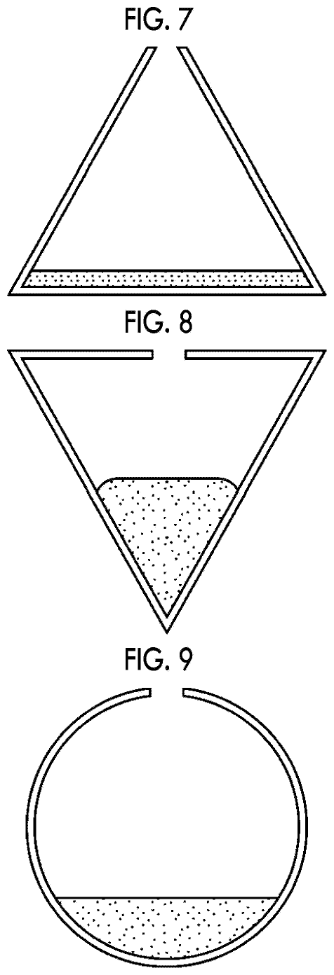

Further, accommodating portions (container) having a cone shape (frustum shape) conceptually shown in FIG. 7, an inverted cone shape conceptually shown in FIG. 8, and a spherical shape conceptually shown in FIG. 9 can also be used.

It should be noted that in the above drawings, hatching indicates an accommodated powder material.

Although the vapor deposition method and the vapor deposition container according to the embodiment of the present invention have been described above, the present invention is not limited thereto, and there is no need to say that various improvements and modifications may be performed without departing from the gist of the present invention.

### EXAMPLES

Hereinafter, the features of the present invention will be described more specifically with reference to Examples.

However, the present invention is not limited to Examples given below. Therefore, the scope of the present invention should not be construed as being limited by the specific examples given below.

### Example 1

Film formation was performed on a substrate by vacuum vapor deposition using a vapor deposition apparatus as shown in FIG. 1.

A 4-inch silicon wafer was used as the substrate.

As a powder material, 8-hydroxyquinoline aluminum in a powder form having an average particle diameter of 1 μm was used. The powder material is a sublimable material.

As a container, a container consisting of a container main body and a lid body having a rectangular planar shape as shown in FIG. 2 was used. The container is made of tantalum with a thickness of 0.15 mm. The accommodating portion was a rectangular cuboid having a bottom surface of 30×30 mm and a height of 20 mm.

As openings, eight circular openings having a diameter of 1 mm were provided. A shape of an opening is circular also in all of the following examples. The openings were provided in a staggered pattern, and intervals were all 1.5 mm.

In the container, as shown in FIG. 2, a container main body and a lid body were engaged with each other and both were fixed by a clamp.

Vapor deposition was performed on the substrate using such a vapor deposition apparatus.

An amount of the powder material charged into the container was 1 g, and the vapor deposition was performed until a film thickness reached 1000 Å.

A vapor deposition pressure was 3×10⁻⁵ Pa.

Heating of the container was performed by energizing the container with a DC current to cause the container to generate heat.

A thermocouple was in contact with a lower surface of the container as a temperature measuring unit. During the vapor deposition, a temperature was measured with the thermocouple, and an input current amount was adjusted such that the temperature of the lower surface of the container was constant at 300° C.

During the film formation, a deposition rate was measured with a rate monitor provided in a vacuum chamber. Measurement of the deposition rate was performed by adjusting a rate monitor coefficient such that the film thickness on the substrate could be known. The measurement of the deposition rate was started 10 seconds after the temperature of the lower surface of the container was stabilized at 300° C. after start of heating of the container.

In addition, a fluctuation width (rate fluctuation) of the deposition rate was measured from a measurement result of the deposition rate. The fluctuation width of the deposition rate is a difference between the maximum value and the minimum value of the deposition rate.

The measurement result of the deposition rate and the rate fluctuation width are shown in Table 1 below.

### Examples 2 to 7, Comparative Example 1 and Comparative Example 2

In a container for accommodating and heating a powder material, the vapor deposition was performed on the substrate in the same manner as in Example 1 except that one or more from among the area of the bottom surface of the accommodating portion, the height of the accommodating portion, the diameter of the opening (opening diameter), the number of the openings, and the intervals of the openings were appropriately modified, and the deposition rate and the rate fluctuation width were measured.

A container of Example 5 has accommodating portion having a square frustum shape in which a bottom surface is 40×40 mm and a ceiling surface is 15×15 mm.

The results are also shown in Table 1 below.

TABLE 1

| | | | | | | Inner | | |
|---|---|---|---|---|---|---|---|---|
| | | Bottom | | | | surface | | |
| | Bottom | area | | Side | Ceiling | area | Opening | Number of |
| | surface | Sb | Height | area | area | S | diameter | openings |
| | [mm] | [mm²] | [mm] | [mm²] | [mm²] | [mm²] | [mm] | Quantity |
| Example 1 | 30 × 30 | 900 | 20 | 2400 | 900 | 4200 | 1 | 8 |
| Comparative | 30 × 30 | 900 | 20 | 2400 | 900 | 4200 | 4 | 8 |
| Example 1 | | | | | | | | |
| Comparative | 30 × 30 | 900 | 20 | 2400 | 900 | 4200 | 0.5 | 8 |
| Example 2 | | | | | | | | |
| Example 2 | 30 × 30 | 900 | 20 | 2400 | 900 | 4200 | 2 | 2 |
| Example 3 | 30 × 30 | 900 | 20 | 2400 | 900 | 4200 | 1 | 8 |
| Example 4 | 20 × 20 | 400 | 40 | 5200 | 400 | 4000 | 1 | 8 |
| Example 5 | 40 × 40 | 1600 | 21 | 2376 | 225 | 4200.9 | 1 | 8 |
| Example 6 | 30 × 30 | 900 | 40 | 4800 | 900 | 6600 | 1 | 8 |
| Example 7 | 30 × 30 | 900 | 10 | 1200 | 900 | 3000 | 1 | 8 |

| | Total | | | Bottom | | | |
|---|---|---|---|---|---|---|---|
| | opening | | Opening | area | Input | | |
| | area | Opening | ratio | ratio | current | Deposition | Rate |
| | O | interval | O/S | Sb/S | amount | rate | fluctuation |
| | [mm²] | [mm] | [%] | [%] | [Ah] | [Å/s] | [Å/s] |
| Example 1 | 6.28 | 1.50 | 0.15 | 21.43 | 15 | 1 | 0.05 |
| Comparative | 100.53 | 1.50 | 2.39 | 21.43 | 15 | 0.7 | 0.5 |
| Example 1 | | | | | | | |
| Comparative | 1.57 | 1.50 | 0.04 | 21.43 | 15 | 0.2 | 0.01 |
| Example 2 | | | | | | | |
| Example 2 | 6.28 | 1.50 | 0.15 | 21.43 | 15 | 1 | 0.2 |
| Example 3 | 6.28 | 0.50 | 0.15 | 21.43 | 15 | 1 | 0.15 |
| Example 4 | 6.28 | 1.50 | 0.16 | 10.00 | 20 | 1 | 0.05 |
| Example 5 | 6.28 | 1.50 | 0.15 | 38.09 | 12 | 1 | 0.05 |
| Example 6 | 6.28 | 1.50 | 0.10 | 13.64 | 12 | 1 | 0.05 |
| Example 7 | 6.28 | 1.50 | 0.21 | 30.00 | 18 | 1 | 0.05 |

For a shape of an accommodating portion, only Example 5 had a square frustum shape, and all of the others had rectangular cuboid shapes
An input current amount was controlled such that container temperatures were 300° C.

As shown in Table 1, according to the vapor deposition method according to the embodiment of the present invention in which the opening ratio O/S (total opening area O/inner surface area S) in the accommodating portion of the container is 0.06% to 2%, a deposition rate of 1 Å/s (sec) can be ensured, and a rate fluctuation of the vapor deposition is small.

In particular, as shown in Examples 1 and 2, by setting the area of the opening to 1 mm² or less, it is possible to prevent a bumping powder material from being projected out of the container and to stabilize a deposition rate. In addition, by setting the intervals between the openings to 1 mm or more as shown in Examples 1 and 3, similarly, it is possible to prevent a bumping powder material from being projected out of the container and to stabilize a deposition rate.

In addition, as shown in Examples 1, 4, and 5, by setting the bottom area ratio Sb/S (bottom area Sb/inner surface area S) of the accommodating portion to 20% or more, stable vapor deposition even with a small input current is possible, and an input current can be reduced by increasing the bottom area ratio.

Further, as shown in Examples 1, 6, and 7, an input current can be reduced by increasing the inner surface area S of the accommodating portion.

With respect to this, in Comparative Example 1 in which the opening ratio O/S in the accommodating portion of the container exceeded 2%, the inside of the accommodating portion cannot have been set to a saturated vapor pressure, and a variation of the deposition rate was great. In addition, in Comparative Example 2 in which the opening ratio O/S in the accommodating portion of the container was less than 0.06%, the deposition rate was as low as 0.2 Å/s.

As can be seen from the above results, the effects of the present invention are obvious.

### EXPLANATION OF REFERENCES

10: vapor deposition apparatus
12: vacuum chamber
14: substrate holder
16, 16A: container
18: vacuum exhaust unit
20: heating unit
20a: DC power source
24: temperature measuring unit
30: container main body
30a: flange portion
32, 32A: accommodating portion
34, 34A: lid body
36: opening

What is claimed is:

1. A vapor deposition method comprising:
in performing vacuum vapor deposition of a powder material,
as a container for accommodating and heating the powder material,
using a container including an accommodating portion configured to accommodate the powder material and at least one opening for releasing vapor of the powder material from the accommodating portion, to perform the vacuum vapor deposition of the powder material by heating the container,
wherein, in a case where an area of an inner surface of the accommodating portion is S and a total area of the opening is O, a ratio of the total area O of the opening to the area S of the inner surface is 0.06% to 2% as a percentage of O/S.

2. The vapor deposition method according to claim 1, wherein the container includes a plurality of the openings.

3. The vapor deposition method according to claim 2, wherein an area of the opening is 1 mm² or less.

4. The vapor deposition method according to claim 2, wherein the openings are spaced apart from each other by 1 mm or more.

5. The vapor deposition method according to claim 1, wherein the opening is circular.

6. The vapor deposition method according to claim 1, wherein, in a case where a bottom area of the accommodating portion is Sb, a ratio of the bottom area Sb to the area S of the inner surface is 20% or more as a percentage of Sb/S in the container.

7. The vapor deposition method according to claim 1, wherein a difference between a vaporization temperature and a decomposition temperature of the powder material is 70° C. or lower.

8. The vapor deposition method according to claim 1, wherein the powder material is sublimable.

9. The vapor deposition method according to claim 1, wherein the container includes a container main body that forms at least a part of the accommodating portion, and a lid body that includes the opening and engages with the container main body, and
the container main body and the lid body are formed of a material that generates heat by energization.

10. The vapor deposition method according to claim 1, wherein the vapor deposition of the powder material is performed while a volume of the powder material is kept in a range of 50% to 5% of a capacity of the accommodating portion.

11. A vapor deposition container that accommodates and heats a material of which vapor deposition is performed in a case of performing vacuum vapor deposition, the vapor deposition container comprising:
an accommodating portion configured to accommodate the material; and
at least one opening for releasing vapor of the material from the accommodating portion,
wherein, in a case where an area of an inner surface of the accommodating portion is S and a total area of the opening is O, a ratio of the total area O of the opening to the area S of the inner surface is 0.06% to 2% as a percentage of O/S.
